(19) United States
(12) Patent Application Publication
(10) Pub. No.: US 2015/0217529 A1
(43) Pub. Date: Aug. 6, 2015

(54) DECOMPRESSING JIG AND A METHOD FOR APPLYING PRESSURE ON A WORKPIECE BY USING THE DECOMPRESSING JIG

(71) Applicant: SINTOKOGIO, LTD., NAGOYA-SHI, AICHI (JP)

(72) Inventors: Masahiko Nagasaka, Toyokawa-shi (JP); Shogo Nakajima, Toyokawa-shi (JP); Osamu Sugino, Toyokawa-shi (JP); Kyoji Furukawa, Shinshiro-shi (JP)

(21) Appl. No.: 14/419,560

(22) PCT Filed: Sep. 13, 2013
(86) PCT No.: PCT/JP2013/074891

§ 371 Date: Feb. 4, 2015

(30) Foreign Application Priority Data
Oct. 12, 2012 (JP) 2012-226629

(51) Int. Cl. B30B 5/02; H01L 21/56

(52) U.S. Cl. CPC B30B 5/02; H01L 21/56

(57) ABSTRACT

To provide a decompressing jig that can apply pressure on a workpiece after a space for accommodating the workpiece is sufficiently decompressed and a method for applying pressure on a workpiece by using the decompressing jig. The decompressing jig 1 is configured by integrating a first member for decompression 10, a second member for decompression 20, a sealing member 30, a first member for preliminary decompression 40, and a second member for preliminary decompression 50. The first member for decompression 10 is formed by spreading a first sheet 12 made of a flexible sheet across a first frame 11. In the first frame 11 a path for suction 15 that is connected to a device for suction via a port for suction 14 and that is connected to a space S for accommodating the workpiece is formed. The first member for preliminary decompression 40 forms a chamber Y for preliminary decompression between it and the first sheet 12 so that the chamber Y can be decompressed.

### TECHNICAL FIELD

The present invention relates to a decompressing jig that decompresses a space for accommodating a workpiece to apply pressure on the workpiece to be subject to a treatment by pressure. It also relates to a method for applying pressure on the workpiece by using the decompressing jig.

### BACKGROUND ART

Conventionally, in a process to apply pressure on a workpiece under a decompressed condition, such as for sealing a semiconductor chip or manufacturing a multi-layer board, a decompressing jig that holds a workpiece under a decompressed condition in it has been used. For example, Japanese Patent Laid-open Publication No. 2011-29516 discloses an invention in which a resin sealant and a semiconductor chip are layered on a substrate to be placed in a space that is surrounded by a flexible membrane. They are then decompressed by using a decompressing jig so that pressure is applied on them by the flexible membrane by the difference in pressure with the atmospheric pressure. Thus they are fixed. Then they are heated while pressure is applied on them to seal them. Japanese Patent Laid-open Publication No. 2003-124628 discloses an invention in which laminated resin sheets are fixed by a flexible cover of a holder for holding the sheets by decompressing the inside of the holder. Then they are hot-pressed by a hot-pressing machine.

By the above inventions, since pressure is applied on the workpiece from the flexible membrane when being decompressed, pressure is applied on the workpiece before the portion near the workpiece is sufficiently decompressed. When such pressure is applied, on the workpiece before being sufficiently decompressed, a void may be generated in the workpiece after the pressure is applied. This has been a problem. This is very apparent when a workpiece is a laminated material or uses a viscous material such as a resin sealant.

The objects of the present invention are to provide a decompressing jig that allows pressure to be applied on a workpiece after the space where the workpiece is accommodated is sufficiently decompressed and to provide a method for applying pressure on a workpiece by using the decompressing jig.

### DISCLOSURE OF INVENTION

To achieve the objects, the first aspect of the present invention is a decompressing jig that decompresses a space for accommodating a workpiece to apply pressure on the workpiece by a pressing device. The decompressing jig comprises a first member for decompression having a first frame that is shaped like a frame and a first sheet that is spread across the first frame. It also comprises a member for holding the workpiece that faces the first member for decompression so that the workpiece is accommodated between the member for holding the workpiece and the first member for decompression. It also comprises a sealing member that is disposed between the first frame and the member for holding the workpiece and that forms the space for accommodating the workpiece by, in an airtight manner, enclosing the space between the first member for decompression and the member for holding the workpiece. It also comprises a first member for preliminary decompression that is disposed to face the first member for decompression on the side opposite the member for holding the workpiece so as to form a chamber for preliminary decompression between the first member for preliminary decompression and the first sheet and that is configured to decompress the chamber for preliminary decompression.

By the first aspect of the present invention, a workpiece is placed in the space for accommodating a workpiece and the chamber for preliminary decompression is decompressed by suction and then air in the space for accommodating the workpiece is suctioned. Thus air in the space for accommodating the workpiece is suctioned while no pressure is applied on the workpiece from the first sheet. Thus, since pressure is being applied on the workpiece after the space for accommodating the workpiece is sufficiently decompressed, bubbles are prevented from remaining in the workpiece, and so a defect such as a void can be prevented from being generated. Since the first sheet is formed of a material that has great flexibility, the workpiece is fixed after the space for accommodating the workpiece is decompressed, so that pressure is then applied on the workpiece.

The second aspect of the present invention is a decompressing jig, which is the one in the first aspect, wherein the member for holding the workpiece is a second member for decompression that comprises a second frame that is disposed to face the first frame and that is shaped like a frame and a second sheet that is spread across the second frame. The decompressing jig comprises a second member for preliminary decompression that is disposed to face the second member for decompression opposite the first member for decompression so as to form a chamber for preliminary decompression between the second member for preliminary decompression and the second sheet and that is configured to decompress the chamber for preliminary decompression.

By the second aspect of the present invention, both the second member for decompression, functioning as the member for holding the workpiece, which second member for decompression has a structure like the first member for decompression, and the second member for preliminary decompression, which has a structure like the first member for preliminary decompression, can be used. By this configuration, since the member for holding the workpiece is formed of a sheet so that the heat capacity is decreased, the workpiece can be quickly heated or cooled. This is advantageous. Further, the second member for preliminary decompression is not deformed toward, the space for accommodating the workpiece when the space for accommodating the workpiece is depressed. Thus neither the first sheet nor the second sheet contacts the workpiece.

The third aspect of the present invention is the decompressing jig, which is the one in the first aspect or second aspect of the present invention, wherein the first member for preliminary decompression or the second member for preliminary decompression is formed so as to have a spacer that is formed to be disposed inside the chamber for preliminary decompression.

By the third aspect of the present invention, since the volume in the chamber for preliminary decompression is reduced by the volume of the spacer, the chamber for preliminary decompression is rapidly decompressed and after being decompressed the first sheet and the second sheet can be prevented from being excessively deformed.

The fourth aspect of the present invention is the decompressing jig, which is the one in the first aspect or second aspect of the present invention, and that further comprises a member for forming the space for accommodating the workpiece that is a plate-like member provided in the member for holding the workpiece and that divides the space for accommodating the workpiece into a second space for accommodating the workpiece and a space for an airflow that connects the second space for accommodating the workpiece to a device for suction.

By the fourth aspect of the present invention, since the space for accommodating the workpiece can be divided into the second space for accommodating the workpiece and the space for an airflow by the member for forming the space for accommodating the workpiece, the workpiece can be prevented from being displaced. Further, a path for suction can be secured and be prevented from being occluded by the displaced workpiece. Further, the second space for accommodating the workpiece can be definitely and quickly suctioned.

The fifth aspect of the present invention is the decompressing jig, which is the one in the fourth aspect of the present invention, and that further comprises a member for positioning the workpiece that is a frame-like and plate-like member that is provided in the member for holding the workpiece and that positions the workpiece.

By the fifth aspect of the present invention, since the workpiece is accurately positioned by the member for positioning the workpiece, the workpiece is not displaced, so that pressure is firmly applied on the workpiece.

The sixth aspect of the present invention is the decompressing jig, which is the one in the first or second aspect of the present invention, wherein the workpiece has a substrate holding a semiconductor chip and a sealant for the semiconductor chip.

Since the treatment by pressure can be carried out after the air is sufficiently suctioned even when the workpiece has a substrate holding a semiconductor chip and a sealant for the semiconductor chip as in the sixth aspect of the present invention, a void can be advantageously prevented from being generated.

The seventh aspect of the present invention is a method for applying pressure on a workpiece, wherein the decompressing jig of claim 1 or 2 and the workpiece are prepared. The method comprises the step of preliminarily decompressing the chamber for preliminary decompression wherein the chamber for preliminary decompression is decompressed by suctioning the chamber. It also comprises the step of placing the workpiece in the space for accommodating the workpiece. It also comprises the step of decompressing the space for accommodating the workpiece by suctioning the space to the extent that no pressure is applied on the workpiece. It also comprises the step of fixing the workpiece by opening the chamber for preliminary decompression to the atmospheric pressure and by tightly contacting the first sheet with the workpiece in the space for accommodating the workpiece. It also comprises the step of applying pressure on the workpiece that is fixed by removing the member for preliminary decompression from the member for decompression.

By the seventh aspect of the present invention, the chamber for preliminary decompression is suctioned to be decompressed at the step of preliminarily decompressing the chamber for preliminary decompression, the workpiece is placed in the space for accommodating the workpiece at the step of placing the workpiece, the space for accommodating the workpiece is suctioned to be decompressed to the extent where no pressure is applied on the workpiece at the step of decompressing, the workpiece is fixed by opening the chamber for preliminary decompression to the atmospheric pressure and by tightly contacting the first sheet with the workpiece in the space for accommodating the workpiece at the step of fixing the workpiece, and pressure is applied by the pressing device on the workpiece that is fixed by removing the member for preliminary decompression from the member for decompression. Thus the workpiece is fixed and pressure is applied on the workpiece after the space for accommodating the workpiece is sufficiently decompressed. Thus no bubble can remain in the workpiece. Further, a defect such as a void can be prevented from being generated.

By the eighth aspect of the present invention, in the method for applying pressure on the workpiece of the seventh aspect, the pressure to decompress the chamber for preliminary decompression is lower than the pressure to decompress the space for accommodating the workpiece.

By determining the pressure to decompress the chamber for preliminary decompression as in the eighth aspect of the present invention, the pressure in the chamber for preliminary decompression is lower than that of the space for accommodating the workpiece. Thus a force toward the chamber for preliminary decompression is generated in the first sheet. Thus the workpiece is subject to no pressure from the first sheet.

By the ninth aspect of the present invention, in the method for applying pressure on the workpiece of the seventh aspect, at the step of applying pressure on the workpiece the pressure that is used to fix the workpiece at the step of fixing the workpiece is used to apply pressure on the workpiece.

If no large pressure is required to apply pressure on the workpiece, the pressure that is used to fix the workpiece at the step of fixing the workpiece can be used to apply pressure on the workpiece as in the ninth aspect of the present invention.

The basic Japanese patent application, No. 2012-226629, filed Oct. 12, 2012, is hereby incorporated by reference in its entirety in the present application.

The present invention will become more fully understood from the detailed description given below. However, the detailed description and the specific embodiments are only illustrations of the desired embodiments of the present invention, and so are given only for an explanation. Various possible changes and modifications will be apparent to those of ordinary skill in the art on the basis of the detailed description.

The applicant has no intention to dedicate to the public any disclosed embodiment. Among the disclosed changes and modifications, those which may not literally fall within the scope of the present claims constitute, therefore, a part of the present invention in the sense of the doctrine of equivalents.

The use of the articles “a,” “an,” and “the” and similar referents in the specification and claims are to be construed to cover both the singular and the plural, unless otherwise indicated herein or clearly contradicted by the context. The use of any and all examples, or exemplary language (e.g., “such as”) provided herein is intended merely to better illuminate the invention, and so does not limit the scope of the invention, unless otherwise stated.

### BRIEF EXPLANATION OF THE DRAWINGS

FIG. 1 illustrates the configuration of the decompressing jig as a first embodiment. FIG. 1(A) shows a plan view and sectional views of the decompressing jig. FIG. 1(B) is a section taken along the line A-A in FIG. 1(A).

FIG. 2 illustrates the configuration of the first member for decompression. FIG. 2(A) shows a plan view taken from above and a sectional view. FIG. 2(B) shows a plan view taken from below. FIG. 2(C) is an enlarged view of the portion “A” in FIG. 2(B).

FIG. 3 illustrates the configuration of the second member for decompression. FIG. 3(A) shows a plan view taken from above and a sectional view. FIG. 3(B) shows a plan view taken from below. FIG. 3(C) is an enlarged view of the portion “A” hi FIG. 3(A).

FIG. 4 illustrates the configuration of the first member for preliminary decompression. FIG. 4(A) shows a plan view taken from above and a sectional view. FIG. 4(B) shows a plan view taken from below.

FIG. 5 illustrates the configuration of the second member for preliminary decompression. FIG. 5(A) shows a plan view taken from above and a sectional view. FIG. 5(B) shows a plan view taken from below.

FIG. 6 illustrates the process for applying pressure on the workpiece by using the decompressing jig.

FIG. 7 also illustrates the process for applying pressure on the workpiece by using the decompressing jig.

FIG. 8 also illustrates the process for applying pressure on the workpiece by using the decompressing jig.

FIG. 9 illustrates a modified member for holding the workpiece. FIG. 9(A) shows a plan view taken from above and a sectional view of a combination of the first member for decompression and the first member for preliminary decompression. FIG. 9(B) shows a sectional view taken along the line A-A in FIG. 9(A).

FIG. 10 illustrates the configuration of the member for forming the space for accommodating the workpiece of the decompressing jig in a second embodiment. FIG. 10(A) shows a plan view taken from above of the second member for decompression on which the member for forming the space for accommodating the workpiece is mounted. FIG. 10(B) shows sectional views taken along the line A-A and the line B-B in FIG. 10(A).

FIG. 11 illustrates the configuration of the member for positioning the workpiece of the decompressing jig in the second embodiment. FIG. 11(A) shows a plan view taken from above of the second member for decompression on which the member for positioning the workpiece is mounted. FIG. 11(B) shows sectional views taken along the line A-A and the line B-B in FIG. 11(A).

FIG. 12 illustrates the configuration of the member for enhancing the stiffness of the decompressing jig in a third embodiment. FIG. 12(A) shows a plan view taken from above. FIG. 12(B) shows a plan view taken from below. FIG. 12(C) shows a sectional view taken along the line A-A in FIG. 12(A).

### BEST MODE FOR CARRYING OUT THE INVENTION

### First Embodiment

A decompressing jig to dispose a workpiece and to decompress a space for accommodating the workpiece of the present invention and a method for applying pressure on the workpiece by using the decompressing jig is now discussed with reference to the drawings.

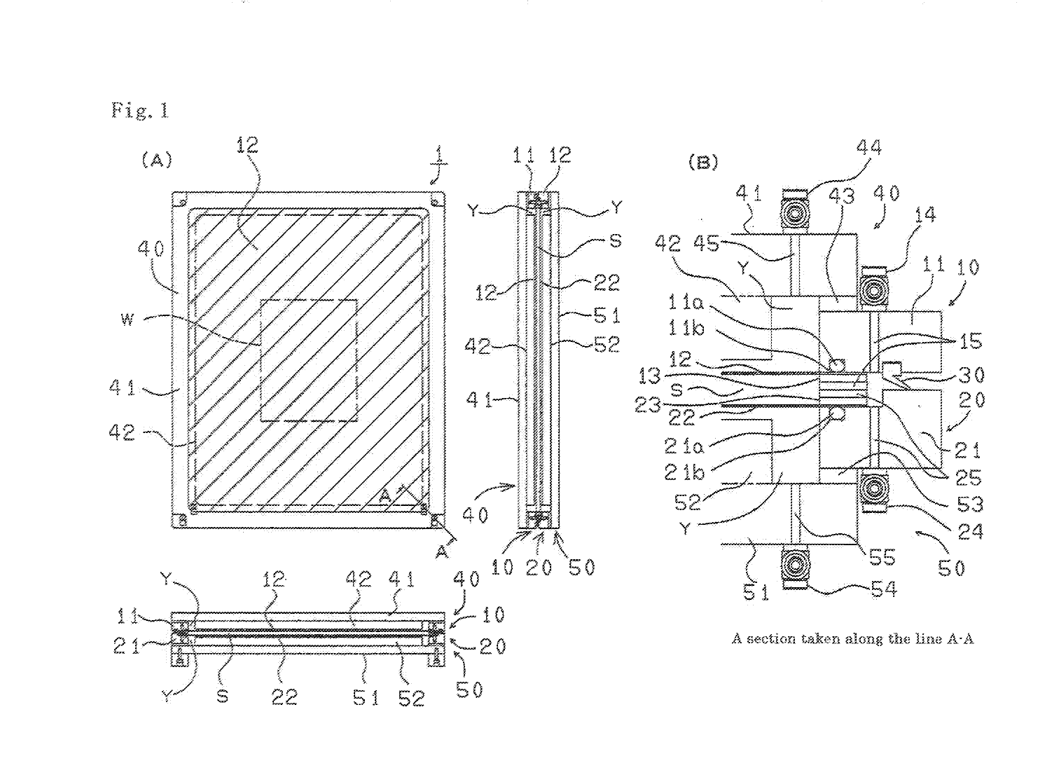

As in FIG. 1, the decompressing jig 1 is configured by integrating a first member for decompression 10, a second member for decompression 20, which is a member for holding the workpiece between it and the first member for decompression 10, a sealing member 30, a first member for preliminary decompression 40, and a second member for preliminary decompression 50. The decompressing jig 1 is discussed as the first member for decompression 10 being disposed above the second member for decompression 20. However, the disposition is not limited to that disposition.

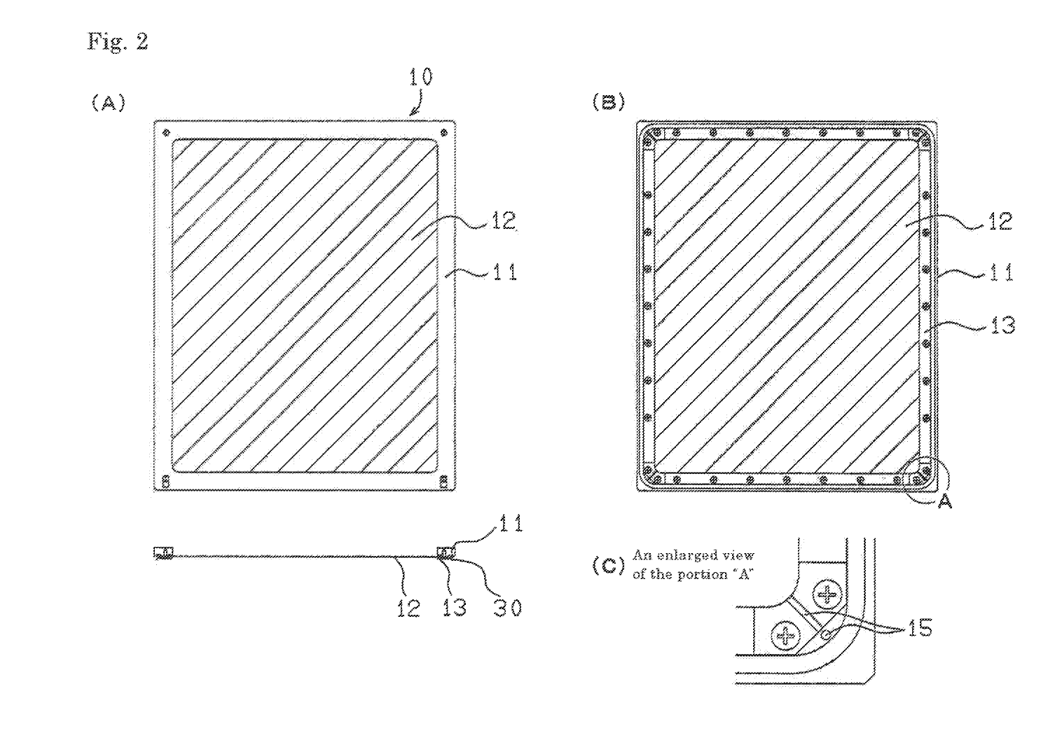

As in FIG. 2, the first member for decompression 10 is formed by spreading a first sheet 12, which is flexible, across a first frame 11. In this embodiment, the first sheet 12 is made of Teflon (a registered trademark), which is a resin.

As in FIG. 1(B), in the first frame 11 a groove for sealing 11b is formed and a seal ring 11a is disposed there. The first sheet 12 is fixed to the first frame 11 via the seal ring 11.a by a first member for restraining 13.

In the first frame 11 a path for suction 15 is formed that is connected to a device for suction (not shown) via a port for suction 14 and is connected, along with a groove that is formed in the first member for restraining 13, to a space S for accommodating the workpiece, which is discussed below. In the present embodiment the ports for suction 14 are provided near two corners of the first frame 11.

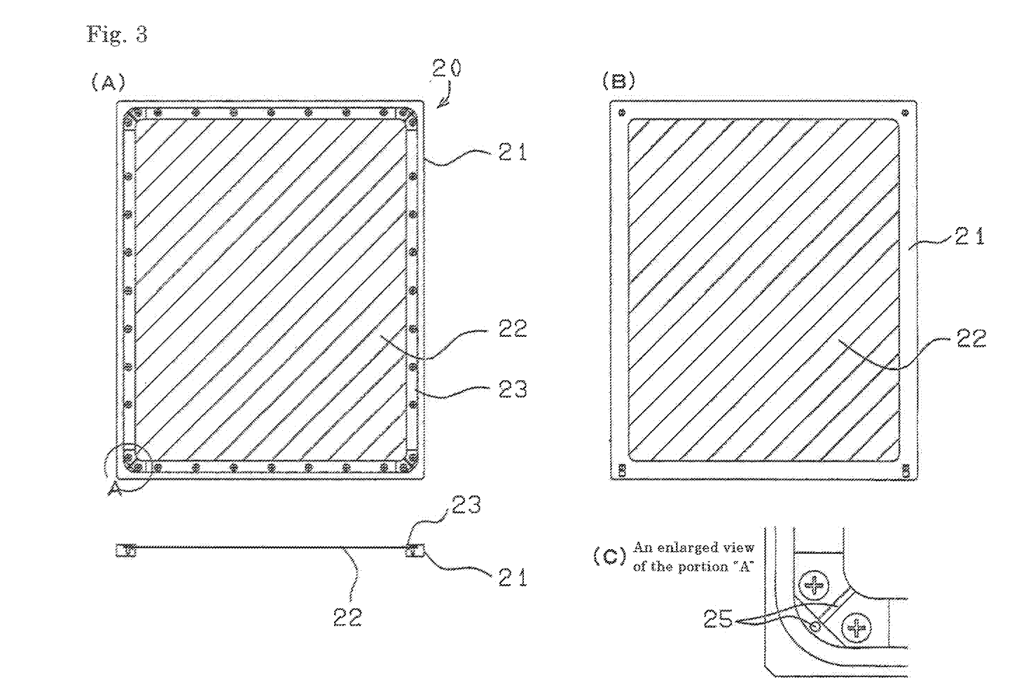

As in FIG. 3, the second member for decompression 20 has a configuration that is similar to that of the first member for decompression 10 so as to be used as a member for holding the workpiece between it and the first member for decompression 10. If the decompressing jig 1 is configured to provide the first member for decompression 10 above the second member for decompression 20 as in the present embodiment, the workpiece W is placed on the second member for decompression 20. The second member for decompression 20 is formed by spreading a second sheet 22, which is flexible, across a second frame 21, which is disposed to face the first frame 11. The second sheet 22 must have a stiffness such that it cannot be significantly deformed when the workpiece W is placed on it. In this embodiment, it is made of stainless steel, which is a metal.

As in FIG. 1(B), in the second frame 21 a groove for sealing 21b is formed and a seal ring 21a is disposed there. The second sheet 22 is fixed to the second frame 21 via the seal ring 21a by a second member for restraining 23.

In the second frame 21 a path for suction 25 is formed that is connected to a device for suction via a port for suction 24 and is connected, along with a groove that is formed in the second member for restraining 23, to a space S for accommodating the workpiece, which is discussed below. In the present embodiment the ports for suction 24 are provided near two corners of the second frame 21.

The paths for suction 15 and 25 are provided in the first frame 11 and the second frame 21, respectively. However, only one path for suction may be provided, in either the first frame 11 or the second frame 21. The number and disposition of the path may be determined based on the shape, size, etc., of the space S for accommodating the workpiece.

The sealing member 30 is disposed between the first frame 11 and the second frame 21 so that a space that is formed between the first sheet 12 and the second sheet 22 is airtight and enclosed so as to provide the space S for accommodating the workpiece W. The sealing member 30 is disposed outside the path for suction 15 in the first frame 11 and the path for suction 25 in the second frame 21 so that the space S for accommodating the workpiece is connected to the paths for suction 15 and 25. So the space S for accommodating the workpiece can be suctioned via the paths for suction 15, 25, to thereby be decompressed. In this embodiment the sealing member 30 is integrated with the first frame 11.

For the sealing member 30 a heat-resistant rubber material, such as silicon rubber, is preferably used. Since silicon rubber is highly adhesive, the space S for accommodating the workpiece can be definitely airtight. Further, since silicon rubber is heat-resistant, it is preferably used when applying pressure on the workpiece W while it is heated at a high temperature.

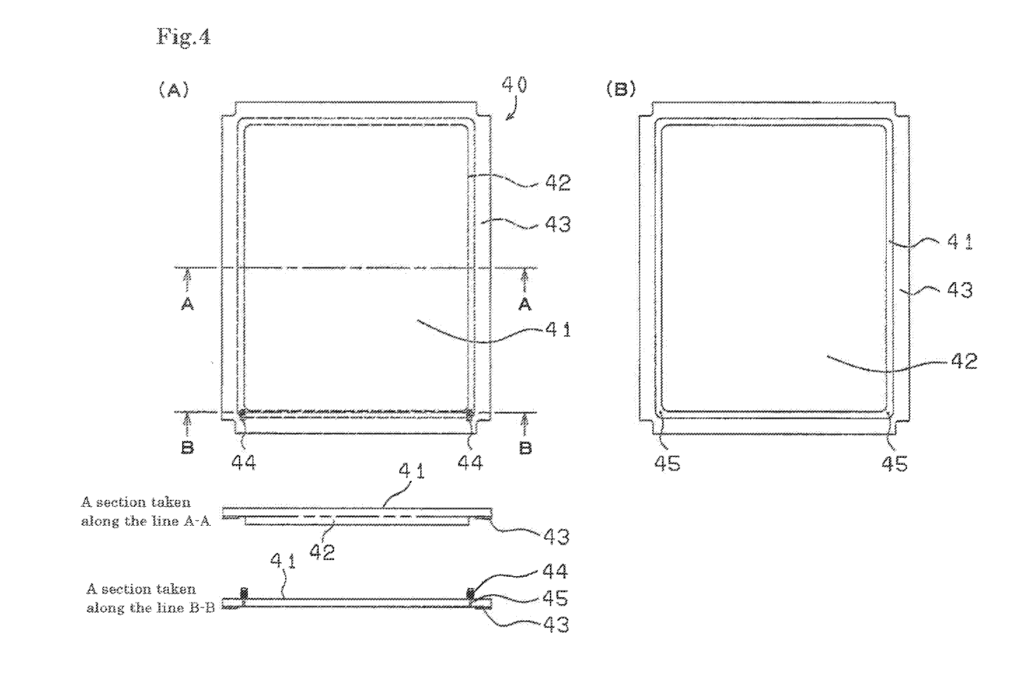

As in FIG. 4, the first member for preliminary decompression 40 comprises a body 41 and a spacer 42. It is disposed to face the first member for decompression 10 via a seal ring 43 on the side opposite the second member for decompression 20. It forms a chamber Y for preliminary decompression between it and the first sheet 12 (see FIG. 1(A)). The spacer 42 is formed to extend toward the inside of the chamber Y for preliminary decompression so as to reduce the volume of the chamber Y. Thus it has effects to quickly decompress the chamber Y and to prevent the first sheet 12 from being excessively deformed when the chamber Y is decompressed.

In the first member for preliminary decompression 40 a path for suction 45 is formed that is connected to the device for suction via a port for suction 44 and that is connected to the chamber Y for preliminary decompression. So the inside of the chamber Y can be decompressed. In this embodiment the ports for suction 44 are provided near two corners of the body 41.

The first member for preliminary decompression 40 is made of a stiff material, such as rigid plastic or metal, so as not to be deformed when the chamber Y is decompressed.

In the first member for preliminary decompression 40 the body 41 and the spacer 42 are integrally formed. However, they may be separately formed.

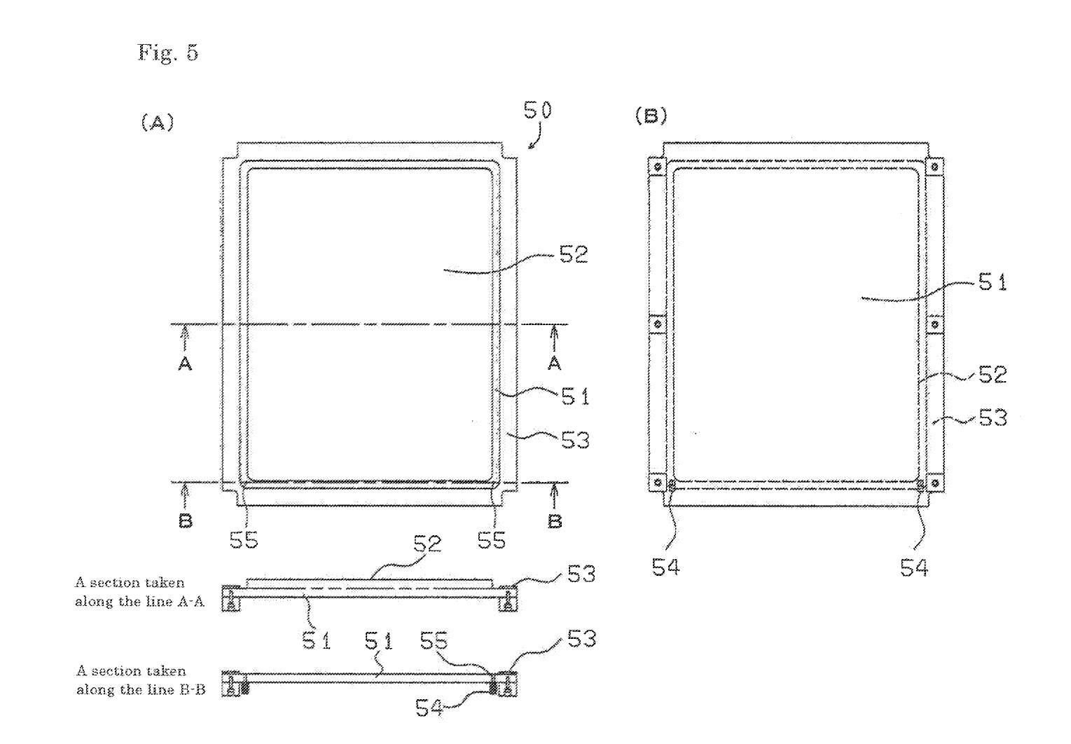

As in FIG. 5, the second member for preliminary decompression 50 has a configuration that is similar to that of the first member for preliminary decompression 40. It comprises a body 51, a spacer 52, a port for suction 54, and a path for suction 55. It is disposed to face the second member for decompression 20 via a seal ring 53 on the side opposite the first member for decompression 10. It forms the chamber Y for preliminary decompression between it and the second sheet 22 (see FIG. 1(A)) so that the chamber Y for preliminary decompression can be decompressed.

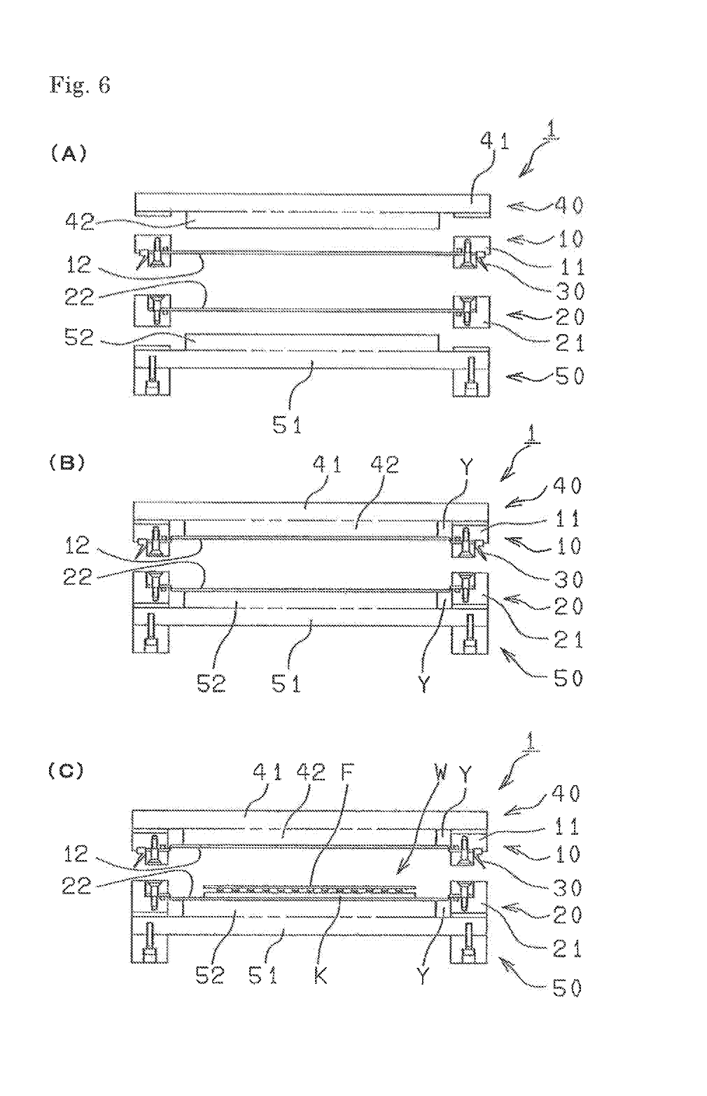

Next, a method for applying pressure on a workpiece by using the decompressing jig 1 is discussed with reference to FIGS. 6, 7, and 8.

First, a workpiece W, which is made by laminating a membrane, is prepared. For example, a workpiece W that is made by laminating a sealant F for a semiconductor chip on a substrate K that has semiconductor chips is used. The sealant F for a semiconductor chip may be a sheet made of epoxy resin.

As in FIG. 6(A), the first member for decompression 10, the second member for decompression 20, the sealing member 30, the first member for preliminary decompression 40, and the second member for preliminary decompression 50, are prepared. Each of the ports for suction 14, 24, 44, 54 is connected to the device for suction (not shown) such as a rotary pump.

At the step of preliminary decompression, as in FIG. 6(B), the chambers Y for preliminary decompression are formed by putting the first member for preliminary decompression 40 on the first member for decompression 10 and by putting the second member for preliminary decompression 50 on the second member for decompression 20. The chambers Y are suctioned to be decompressed by the device for suction.

At the next step, of placing the workpiece, as in FIG. 6(C), the workpiece W is disposed, i.e., placed, on the second sheet 22 of the second member for decompression 20.

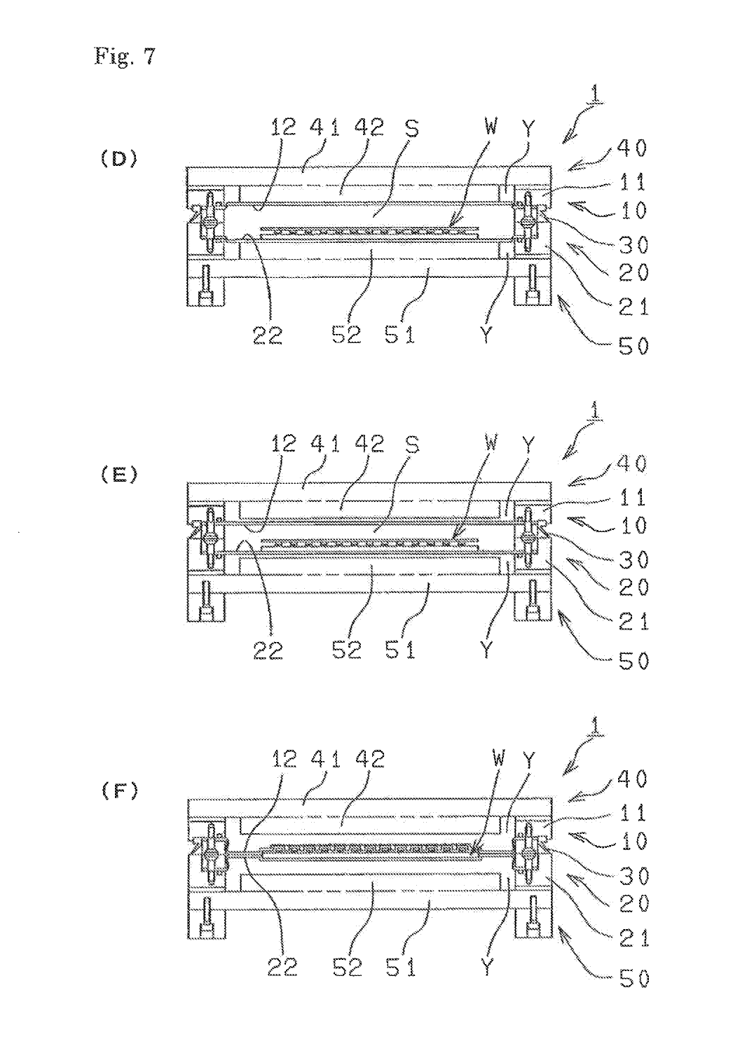

Next, as in FIG. 7(D), the first frame 11 of the first member for decompression 10 is placed on the second frame 21 of the second member for decompression 20 via the sealing member 30, so that the first sheet 12 faces the second sheet 22. So the space S for accommodating the workpiece is formed so that the workpiece W is disposed inside of it. That is, the workpiece W is accommodated and held between the first member for decompression 10 and the second member for decompression 20. At this time, the first member for decompression 10 and the second member for decompression 20 are equipped with the first member for preliminary decompression 40 and the second member for preliminary decompression 50, respectively.

At the next step, of decompression, as in FIG. 7(E), the space S for accommodating the workpiece is suctioned by the device for suction, to be decompressed to a predetermined pressure. The predetermined pressure is a pressure at which no pressure is applied by the first sheet 12 on the workpiece W. For example, the pressure inside the chamber V for preliminary decompression is equal to, or below, the pressure at which the space S for accommodating the workpiece is decompressed. Thus the pressure inside the chamber Y for preliminary decompression is lower than the pressure inside the space S for accommodating the workpiece, so that a force toward the chamber Y is generated in the first sheet 12. So no pressure is applied by the first sheet 12 on the workpiece W, so that the first sheet 12 does not tightly contact the workpiece W. Further, the first sheet 12 cannot contact the workpiece W because it cannot sag. If the first sheet 12 were too stiff, then no pressure could be applied by the first sheet 12 on the workpiece W even if the above requirements were not met. The words “tightly contact” mean a state where one object airtightly adheres to another. For example, when the space for accommodating the workpiece is decompressed, the first sheet. 12 sags toward the workpiece W to thereby adhere to it while pressure is applied on the workpiece W. The state for tightly contacting does not occur when the workpiece W is just placed on the second sheet 22.

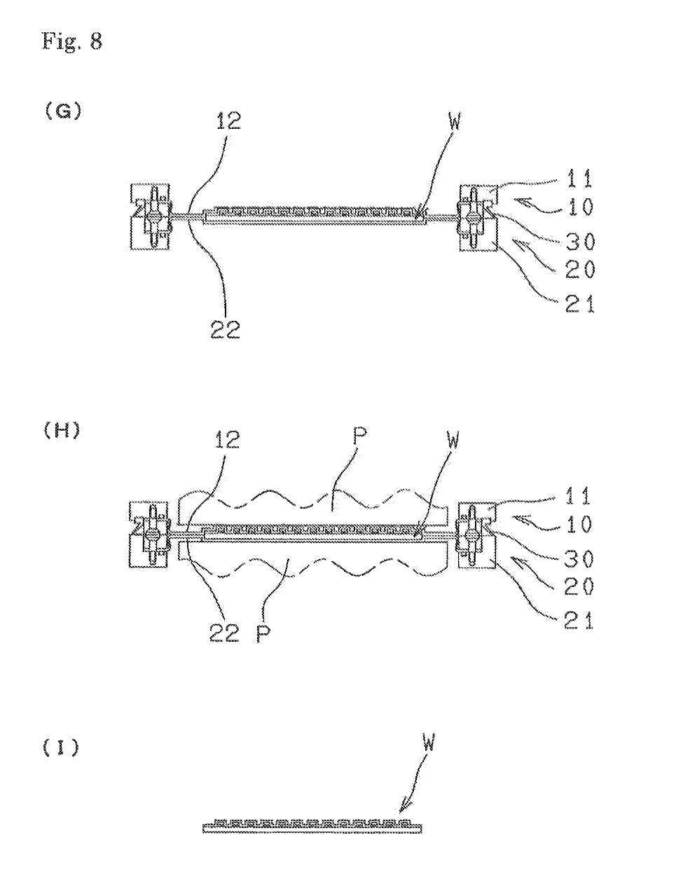

At the next step, of fixing, the chambers Y for preliminary decompression are opened, to thereby be at atmospheric pressure. At this time, the space S for accommodating the workpiece is decompressed. Since the first sheet 12 is made of a material that is sufficiently flexible, the first sheet 12 sags toward the workpiece W due to the difference between the pressure inside the space S for accommodating the workpiece and atmospheric pressure as in FIG. 7(F). So the first sheet 12 applies pressure on the workpiece W so as to tightly contact it. Thus the workpiece W is fixed without air being trapped. Next, as in FIG. 8(G), the first member for preliminary decompression 40 and the second member for preliminary decompression 50 are removed from the first member for decompression 10 and the second member for decompression 20, respectively.

At the next step, of applying pressure, as in FIG. 8(H), pressure is applied by a pressing device P on the workpiece W that is fixed by the first member for decompression 10 and the second member for decompression 20. When the workpiece W is fed to, and taken out of, the pressing device P, the workpiece W is fixed in advance by the decompressing jig 1. Thus the workpiece W can be prevented from being displaced by a shock during transportation. After applying pressure on the workpiece, as in FIG. 8(1), the workpiece W is taken out of the decompressing jig 1. Thus a series of steps is completed.

For example, a single-shaft press may be used as the pressing device P. Since the first member for preliminary decompression 40 and the second member for preliminary decompression 50 are removed before applying pressure, pressure can be applied on the workpiece by a rigid structure, such as a flat plate for pressing, a pressing die, or a pressing roll. Thus great pressure can be applied on the workpiece.

A hot press that applies pressure on a workpiece while heating it or a cold press that applies pressure on a workpiece while cooling it may be used as the pressing device P. Further, the pressing device may be equipped with a preliminary heater that preliminarily heats the decompressing jig 1 and the workpiece W or a residual-heat remover that cools the decompressing jig 1 and the workpiece W. By doing so, the productivity can be improved by definitely and quickly heating or cooling the workpiece W. Further, the workpiece W can be easily heated or cooled, since the first member for preliminary decompression 40 and the second member for preliminary decompression 50 are removed to heat or cool the workpiece W. Even if the workpiece W were to be made of a material that warps when it is heated, it would be heated after being fixed by the decompressing jig 1. So the productivity is improved and the quality of products is also improved.

Since the decompressing jig 1 is separate from the pressing device P, the workpiece W can be set on the decompressing jig 1 in advance outside the pressing device P. Thus the productivity can be improved. The steps of decompressing the chambers Y for preliminary decompression, decompressing the space S for accommodating the workpiece, and opening the chambers Y for preliminary decompression to the atmosphere (FIGS. 6, 7, and 8, [a] to [G] and [I]), can all be performed outside the pressing device P. So among the series of steps, only the step of applying pressure (FIG. 8 [H]) is performed by using the pressing device P. So if a plurality of decompressing jigs 1 are prepared, the workpieces W can be fed to the pressing device P one after another. Thus the productivity can be dramatically improved.

By the decompressing jig 1 that has the above-mentioned structure, the space S for accommodating the workpiece is sufficiently suctioned while no pressure from the first sheet 12 is applied on the workpiece WI and the first sheet 12 does not tightly contact the workpiece W. Then the decompressing jig 1 can fix the workpiece W by contacting the first sheet 12 with the workpiece W that is disposed in the space S for accommodating the workpiece. So no air remains in the workpiece W, so as to prevent a defect, such as voids.

The method for applying pressure on a workpiece by using the decompressing jig 1 is preferably used when the workpiece W is made of laminated materials wherein, air easily remains between the layers or of an adhesive material in which air easily remains at a low pressure, such as a sealant for a substrate and a semiconductor chip, which sealant is discussed above. It is also preferably used when the workpiece W is made of a sheet for dissipating heat that is sandwiched between a semiconductor chip and a heat sink or a sheet that is to be imprinted wherein no air is allowed to remain. It is also preferably used when no pressure should be applied on a workpiece W before the space S for accommodating the workpiece is completely decompressed, as, for example, when the workpiece W is made of slurry.

If the pressure required to be applied on the workpiece W is not large, pressure that is used for fixing the workpiece W at the step of fixing (for tightly contacting the first sheet 12 with the workpiece W) may be used for applying pressure on the workpiece W, not pressure applied by the pressing device. That is, at the step of applying pressure, the pressure to fix the workpiece W at the step of fixing is applied.

Though in this embodiment the first sheet 12 is made of Teflon (a registered trademark), a resin, and the second sheet 22 is made of stainless steel, a metal, the raw materials are not limited to these.

A fiber-reinforced rubber-sheet that is dispersion-strengthened by whiskers of glass or ceramics or that is made by integrating a foundation cloth with thin rubber sheets on both surfaces may be used for the first sheet 12 or the second sheet 22.

A rubber-coated cloth, that has both rigidity and flexibility is preferably used for the first sheet 12 and the second sheet 22. For the foundation cloth of the rubber-coated cloth a sheet made of fluorine fibers, polyimide fibers, polyphenylene-sulfide fibers, aramid fibers, nylon fibers, polyester fibers, polyamide fibers, polyurethane fibers, cotton fibers, glass fibers, or the like may be used.

For rubber for a thin coating, fluorine rubber, nitrile rubber, urethane rubber, chloroprene rubber, natural rubber, silicon rubber, or the like may be used. A surfactant agent, such as tri-alkoxyl alkyl phosphate, or carbon powders, may be added to the rubber as an antistatic agent.

When heat-resistance is required for the first sheet 12 and the second sheet 22, as, for example, where the decompressing jig 1 is used at a high temperature, e.g., 160° C., glass fibers or heat-resistant synthetic fibers, for example, are preferably used for the foundation cloth and fluorine rubber and silicon rubber are preferably used for the rubber. The heat-resistant synthetic fibers are fibers that can be used to keep the space S for accommodating the workpiece airtight at the operating temperature of the decompressing jig 1. Glass fibers and heat-resistant nylon are preferably used for them.

When the fiber-reinforced rubber sheet is used for the first sheet 12 and the second sheet 22, since their degrees of thermal expansion are low, the workpiece W is prevented from being displaced due to the difference in the degrees of thermal expansion of the first sheet 12 and the second sheet 22 and the other members. Further, they are resilient and flexible so that they return to their original shapes after any external force that may cause them to be deformed is removed. So their shapes are not changed after repeated uses. Since they have buffering effects to equalize the pressure to be applied to the workpiece W, uniform pressure is applied from the pressing device on the workpiece W without generating any local pressure. Since the sheets made of fiber-reinforced rubber are durable, they are not easily damaged by a corner of the workpiece W or a jig.

A polyimide sheet may be used for both the first sheet 12 and the second sheet 22. By doing so, since it is heat-resistant, pressure can be applied on the workpiece W at a high temperature.

### <Variations>

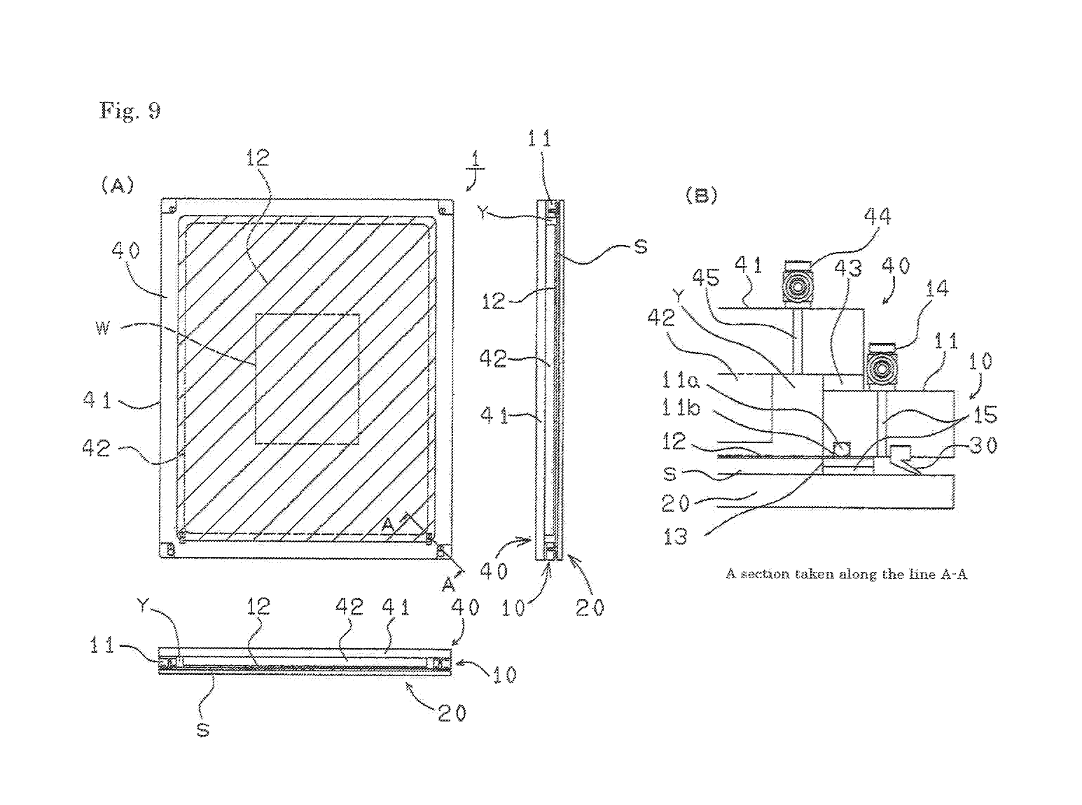

As in FIG. 9, the second member for decompression 20 may be shaped as a flat member. By doing so, the configuration becomes simpler. Further, since the portion for holding the workpiece W is rigid, it can stably hold the workpiece W. So it is preferably used for a workpiece that has a low hardness, such as one made of slurry. Further, it is preferable that the second member for decompression 20, which is shaped as a flat member, have the workpiece W that has a low hardness be mounted on it. If the workpiece W is heated or cooled at the step of applying pressure on it, the configuration shown in FIG. 3 is better. That is because it can be quickly heated or cooled, since the heat capacity is reduced.

If the size of the chamber Y for preliminary decompression is small or the distance between the body 41 and the first sheet 12 is small so that the first sheet 12 is not greatly deformed, no spacer 42 may be formed on the first member for preliminary decompression 40. The same applies to the second member for preliminary decompression 50.

In the above embodiment, the first sheet 12 is fixed to the first frame 11 by means of the first member for restraining 13 via the seal ring 11a. However, the method for fixing the first sheet 12 is not limited to that. For example, the first sheet 12 may be directly fixed to the first frame 11 by an adhesive. The same applies to fixing the second sheet 22.

If the first sheet 12 is so rigid that it is not deformed toward the workpiece W, so that thus it tightly contacts the workpiece W by the differential pressure between the space S for accommodating the workpiece and the atmosphere, the workpiece W may be fed to the next step, of applying pressure, while it is not fixed.

### Second Embodiment

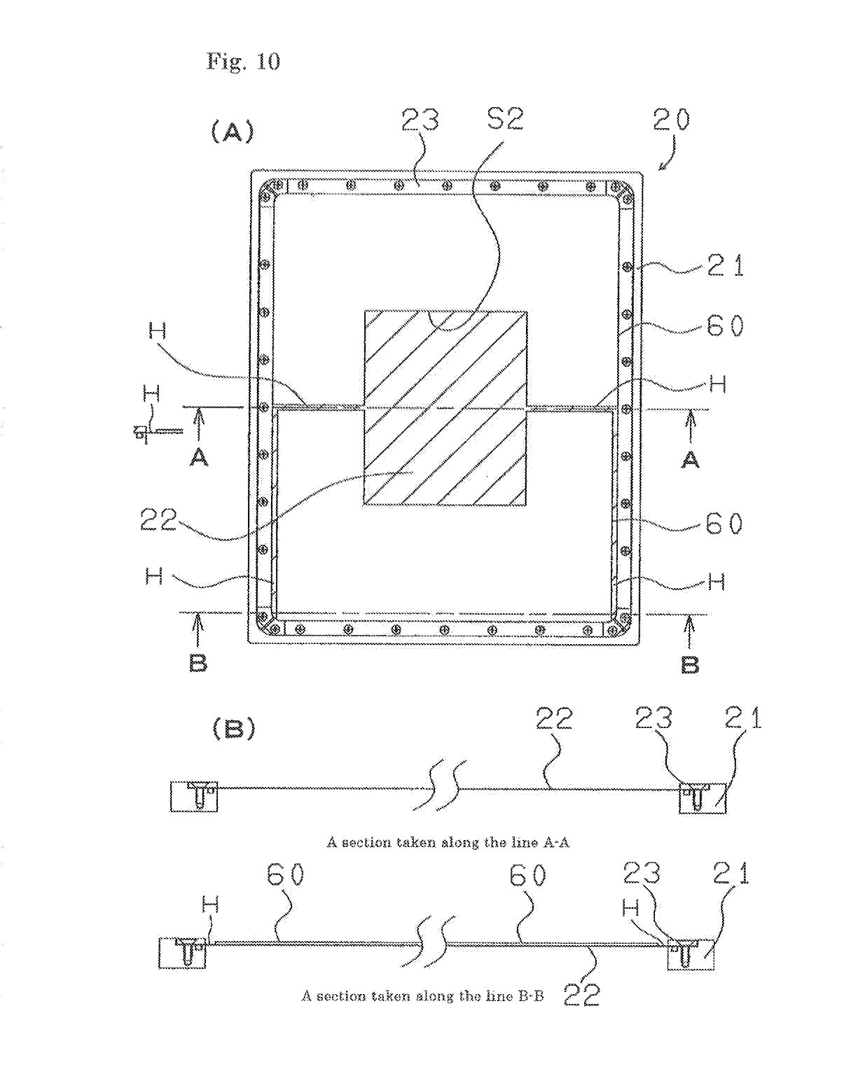

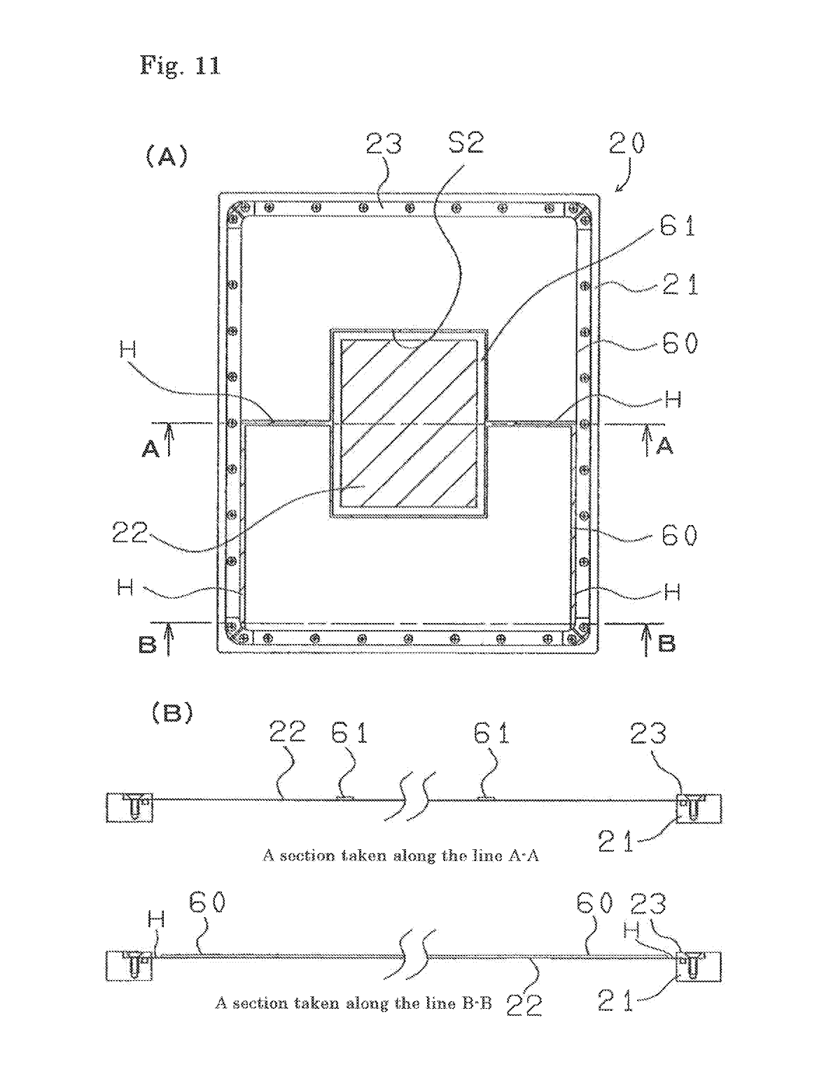

The second embodiment of the decompressing jig for the workpiece of the present invention is now discussed with reference to the drawings. The elements that are the same as or similar to the elements of the first embodiment are denoted by the same numbers and the explanations for them are omitted. In the sectional views of FIGS. 10(A) and 11(A) portions of elements are enlarged so that their configurations become clear.

In this embodiment the configuration of the second member for decompression 20 is varied. As in FIG. 10, a member 60 for forming the space for accommodating the workpiece is formed. It divides the space S for accommodating the workpiece that is sandwiched between the first sheet 12 and the second sheet 22 into a second space S2 for accommodating the workpiece W and a space H for an airflow. The space H for an airflow is used for suctioning the second space S2. In this embodiment the member 60 for forming the space for accommodating the workpiece is made of stainless steel, so as to be thinner than the workpiece W. It is fixed to the second sheet 22 by an adhesive.

The second space S2 for accommodating the workpiece is shaped to match the workpiece W. In this embodiment it is shaped as a rectangle. The space H for an airflow is formed as a path between the periphery of the member 60 for forming the space for accommodating the workpiece and the periphery of the second space S2 for accommodating the workpiece. It connects the second space S2 for accommodating the workpiece to the paths for suction 15, 25. In the embodiment shown in FIG. 10(A) the member 60 for forming the space for accommodating the workpiece is composed of two elements. The first element is about half the size of the second sheet 22 and has a void for the second space 82 for accommodating the workpiece. The second element of it is smaller than the first element since the periphery is formed to be the space H for an airflow. Between the first element and the second element the space H for an airflow is formed as the path between the second space S2 for accommodating the workpiece and the periphery. By forming the member 60 for forming the space for accommodating the workpiece as discussed, the member 60 can be easily manufactured.

If the member 60 for forming the space for accommodating the workpiece is used, the workpiece W is prevented from being displaced. Further, the space for an airflow is secured for suction so that the path for suction is prevented from being clogged by the displacement of the workpiece W. So the inside of the second space S2 for accommodating the workpiece is definitely and quickly suctioned.

As in FIG. 11, a member 61 for positioning the workpiece may be formed inside the member 60 for forming the space for accommodating the workpiece, i.e., inside the second space S2 for accommodating the workpiece. The member 61 is shaped as a frame, to thereby position the workpiece W. By doing so the workpiece W is accurately positioned by the member 61. Thus the workpiece W is prevented from being displaced, so that pressure is stably applied on it. The member 61 for positioning the workpiece is formed to be thinner than the member 60 for forming the space for accommodating the workpiece. Thus when the member 61 for positioning the workpiece is shaped as a closed loop, the space H for an airflow is not occluded.

The member 60 for forming the space for accommodating the workpiece may be formed on the first sheet 12. Further, only the member 61 for positioning the workpiece can be formed without the member 60 for forming the space for accommodating the workpiece.

### Third Embodiment

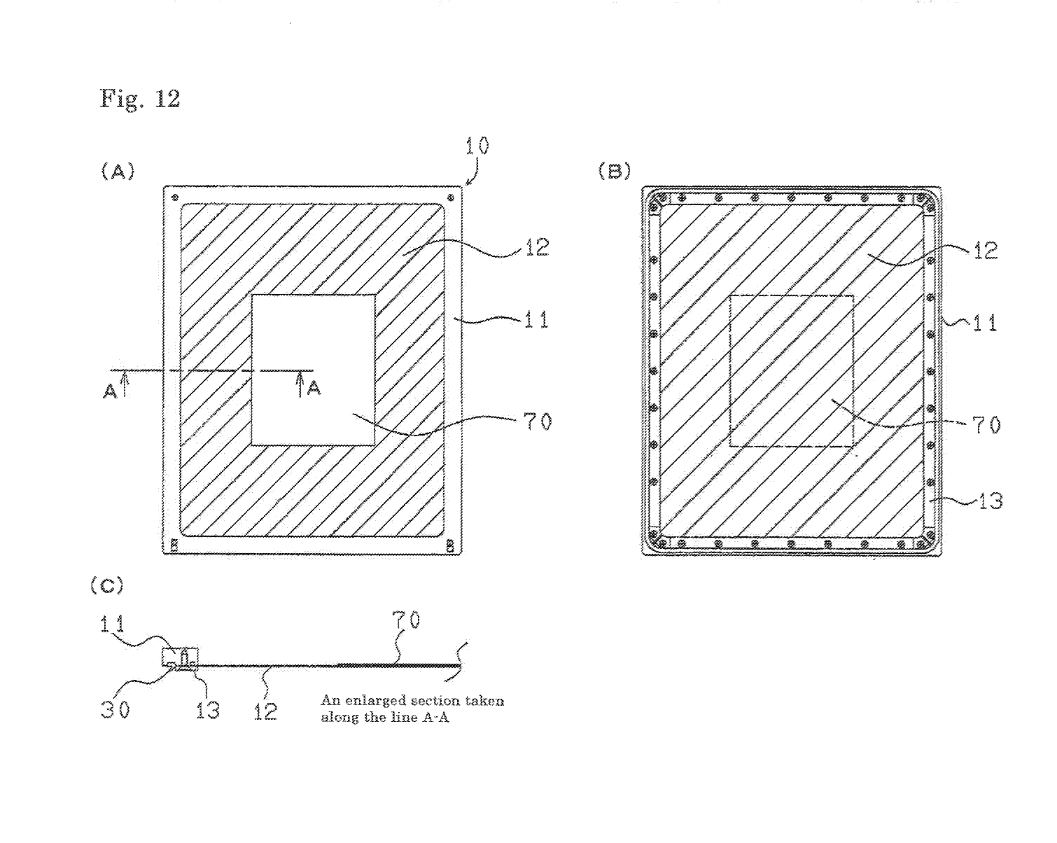

As in FIG. 12, a member 70 for enhancing the stiffness may be formed on the first sheet 12 on the side opposite the workpiece W. It is made of a material that is more rigid than that of the first sheet 12. It is shaped as a rectangle. It is disposed at a position that corresponds to a position where the workpiece W is accommodated, so that pressure is applied on it. It is sized to be greater than the outer shape of the workpiece W. The material for making the member 70 for enhancing the stiffness may be a metal, especially stainless steel.

By the above-mentioned configuration, some degree of stiffness can be imparted to at least a portion of the first sheet 12 by the member 70 for enhancing the stiffness. Thus if the workpiece W were to have a concavo-convex shape, the first sheet 12 would be prevented from being inserted in, and adhering to, a concavity. So the workpiece W that is made of a material that easily adheres to the first sheet 12 and is breakable is prevented from being damaged. Further, the configuration is preferably used when pressure is applied only on the convexity of the workpiece F.

In this embodiment, the member 70 for enhancing the stiffness is formed on the side opposite the workpiece W. However, it can be formed at the side of the workpiece W. By doing so, the first sheet 12 does not directly contact the workpiece W. So the workpiece W that is made of a material that easily adheres to the first sheet 12 and is breakable is prevented from being damaged.

### <Advantageous Effects by the Embodiments>

By using the decompressing jig 1 or the method for applying pressure on the workpiece of the present embodiments, the workpiece W is disposed in the space S for accommodating the workpiece, the chamber Y for preliminary decompression is suctioned to be decompressed, and then the space S for accommodating the workpiece is suctioned. So no pressure is applied on the workpiece W by the first sheet, so that the first sheet does not tightly contact the workpiece W. During this condition the space S for accommodating the workpiece is suctioned. Further, since the first sheet 12 is flexible, the first sheet 12 tightly contacts the workpiece W that is disposed in the space S, to thereby fix the workpiece W. Thus pressure is applied on the workpiece W after the space S for accommodating the workpiece is sufficiently decompressed. So air is prevented from remaining in the workpiece W, to thereby prevent a defect such as voids from being generated. Further, the decompressing jig 1 and the method are preferably used when the workpiece W is made of a material that requires that no pressure be applied on it before the space S for accommodating the work is completely decompressed.

### Other Embodiments

The decompressing jig 1 of the present invention can be used for the process for forming a ceramic molding as in the following:

1. Shaping slurry material into a tape to obtain a tape-like molded item.
2. Drying the tape-like molded item by heating it under decompressed pressure by using the decompressing jig. So the time necessary to dry it can be reduced.
3. Opening the chamber for preliminary decompression to the atmosphere to take out the member for preliminary decompression.
4. Applying pressure on, and heating, the dried tape-like molded item so as to increase the density. For doing so, the space for accommodating the workpiece may be under decompressed pressure and the tape-like molded item may not be fixed. In this case the space for accommodating the workpiece may be opened to the atmosphere or be gas-charged.

Any slurry material other than ceramic material can be formed by the same process.

### Working Example

In this working example, a substrate that holds a semiconductor chip is sealed by an epoxy sheet by using the decompressing jig that is discussed in the first embodiment.

A sheet made of Teflon (a registered trademark) that is 300 μm thick and is reinforced by a glass cloth is used for the first sheet. A stainless plate 300 μm thick that is mirror-finished on both sides is used for the second sheet. Both the first frame and the second frame are made of aluminum. Both the first member for preliminary decompression and the second member for preliminary decompression are constructed by a transparent acrylic resin.

The first member for decompression and the second member for decompression are paired with the first member for preliminary decompression and the second member for preliminary decompression, respectively, to carry out the step of preliminary decompression. The chamber for preliminary decompression is decompressed by a rotary pump so that the internal pressure is −98 kPa.

At the next step, of placing the workpiece an epoxy sheet is laminated over a substrate that holds a semiconductor chip. Then it is disposed on the second sheet. The first frame of the first member for decompression is placed on the second frame of the second member for decompression via the sealing member so that the workpiece is accommodated within the space for accommodating the workpiece.

At the next step, of decompressing, the space for accommodating the workpiece is suctioned by a rotary pump. The internal pressure in the space for accommodating the workpiece is controlled by a vacuum regulator to be within the range of −95 to 0 kPa.

At the next step, of fixing, the chamber for preliminary decompression is opened to the atmosphere so that the workpiece is fixed to be fed to the step of applying pressure.

At the next step, of applying pressure, pressure is applied on the workpiece by a single-shaft press that has a hot pressing plate that can apply pressure on the workpiece. If the temperature of the hot pressing plate were to be too low, then the sealant would not become hardened. If it were to be too high, then the sealant would deteriorate. Thus it is preferable that it be 40-200° C. It is set at 120° C. in this embodiment, if the pressure for pressing were to be too low, then the workpiece would be insufficiently sealed. If it were to be too high, then the semiconductor chip would be damaged. Thus it is preferable that it be 100-3,000 kPa. It is set at 500 kPa in this embodiment. If the duration for pressing were to be too short, then the workpiece would be insufficiently sealed. If it were to be too long, then the productivity would be decreased. Thus it is preferable that it be 1-60 seconds. It is set for 5 seconds in this embodiment.

By the above-mentioned process a semiconductor chip that is sealed without voids is manufactured.
1. a decompressing jig
10. a first member for decompression
11. a first frame
12. a first sheet
14. a port for suction
15. a path for suction
20. a second member for decompression
21. a second frame
22. a second sheet
24. a port for suction
25. a path for suction
30. a sealing member
40. a first member for preliminary decompression
41. a body
42. a spacer
50, a second member for preliminary decompression
60. a member for forming the space for accommodating the workpiece
61. a member for positioning the workpiece
70. a member for enhancing the stiffness
S. a space for accommodating the workpiece
S2. a second space for accommodating the workpiece
W. a workpiece
H. a space for an airflow

1. A decompressing jig that decompresses a space for accommodating a workpiece to apply pressure on the workpiece by a pressing device, the decompressing jig comprising:
a first member for decompression having a first frame that is shaped like a frame and a first sheet that is spread across the first frame;
a member for holding the workpiece that faces the first member for decompression so that the workpiece is accommodated between the member for holding the workpiece and the first member for decompression;
a sealing member that is disposed between the first frame and the member for holding the workpiece and that forms the space for accommodating the workpiece, in an airtight manner, by enclosing the space between the first member for decompression and the member for holding the workpiece; and
a first member for preliminary decompression that is disposed to face the first member for decompression on the side opposite the member for holding the workpiece so as to form a chamber for preliminary decompression between the first member for preliminary decompression and the first sheet and that is configured to decompress the chamber for preliminary decompression.

2. The decompressing jig of claim 1, wherein the member for holding the workpiece is a second member for decompression that comprises a second frame that is disposed to face the first frame and that is shaped like a frame and a second sheet that is spread across the second frame, the decompressing jig comprising:
a second member for preliminary decompression that is disposed to face the second member for decompression opposite the first member for decompression so as to form a chamber for preliminary decompression between the second member for preliminary decompression and the second sheet and that is configured to decompress the chamber for preliminary decompression.

3. The decompressing jig of claim 1, wherein the first member for preliminary decompression or the second member for preliminary decompression is formed so as to have a spacer that is formed to be disposed inside the chamber for preliminary decompression.

4. The decompressing jig of claim 1, further comprising:
a member for forming the space for accommodating the workpiece that is a plate-like member provided in the member for holding the workpiece and that divides the space for accommodating the workpiece into a second space for accommodating the workpiece and a space for an airflow that connects the second space for accommodating the workpiece to a device for suction.

5. The decompressing jig of claim 4, further comprising:
a member for positioning the workpiece that is a frame-like and plate-like member that is provided in the member for holding the workpiece and that positions the workpiece.

6. The decompressing jig of claim 1, wherein the workpiece has a substrate holding a semiconductor chip and a sealant for the semiconductor chip.

7. A method for applying pressure on a workpiece, wherein the decompressing jig of claim 1, and the workpiece are prepared, the method comprising the steps of:
preliminarily decompressing the chamber for preliminary decompression wherein the chamber for preliminary decompression is decompressed by suctioning the chamber;
placing the workpiece in the space for accommodating the workpiece;
decompressing the space for accommodating the workpiece by suctioning the space to the extent that no pressure is applied on the workpiece;
fixing the workpiece by opening the chamber for preliminary decompression to the atmospheric pressure and by tightly contacting the first sheet with the workpiece in the space for accommodating the workpiece; and
applying pressure on the workpiece that is fixed by removing the member for preliminary decompression from the member for decompression.

8. The method for applying pressure on the workpiece of claim 7, wherein the pressure to decompress the chamber for preliminary decompression is lower than the pressure to decompress the space for accommodating the workpiece.

9. The method for applying pressure on the workpiece of claim 7, wherein at the step of applying pressure on the workpiece the pressure that is used to fix the workpiece at the step of fixing the workpiece is used to apply pressure on the workpiece.

10. The decompressing jig of claim 2, wherein the first member for preliminary decompression or the second member for preliminary decompression is formed so as to have a spacer that is formed to be disposed inside the chamber for preliminary decompression.

11. The decompressing jig of claim 2, further comprising:
a member for forming the space for accommodating the workpiece that is a plate-like member provided in the member for holding the workpiece and that divides the space for accommodating the workpiece into a second space for accommodating the workpiece and a space for an airflow that connects the second space for accommodating the workpiece to a device for suction.

12. The decompressing jig of claim 11, further comprising:
a member for positioning the workpiece that is a frame-like and plate-like member that is provided in the member for holding the workpiece and that positions the workpiece.

13. The decompressing jig of claim 2, wherein the workpiece has a substrate holding a semiconductor chip and a sealant for the semiconductor chip.

14. A method for applying pressure on a workpiece, wherein the decompressing jig of claim 2, and the workpiece are prepared, the method comprising the steps of:
preliminarily decompressing the chamber for preliminary decompression wherein the chamber for preliminary decompression is decompressed by suctioning the chamber;
placing the workpiece in the space for accommodating the workpiece;
decompressing the space for accommodating the workpiece by suctioning the space to the extent that no pressure is applied on the workpiece;
fixing the workpiece by opening the chamber for preliminary decompression to the atmospheric pressure and by tightly contacting the first sheet with the workpiece in the space for accommodating the workpiece; and
applying pressure on the workpiece that is fixed by removing the member for preliminary decompression from the member for decompression.

15. The method for applying pressure on the workpiece of claim 14, wherein the pressure to decompress the chamber for preliminary decompression is lower than the pressure to decompress the space for accommodating the workpiece.

16. The method for applying pressure on the workpiece of claim 14, wherein at the step of applying pressure on the workpiece the pressure that is used to fix the workpiece at the step of fixing the workpiece is used to apply pressure on the workpiece.
